(19) United States
(12) Patent Application Publication
(10) Pub. No.: US 2010/0283065 A1
(43) Pub. Date: Nov. 11, 2010

(54) LED DEVICE WITH A LIGHT EXTRACTING ROUGH STRUCTURE AND MANUFACTURING METHODS THEREOF

(75) Inventor: Jui-Kang Yen, (US)

Correspondence Address: MARTINE PENILLA & GENCARELLA, LLP, 710 LAKEWAY DRIVE, SUITE 200, SUNNYVALE, CA, 94085, US

(73) Assignee: Semileds Optoelectronics Co., Ltd., Chu-Nan (TW)

(21) Appl. No.: 12/558,476

(22) Filed: Sep. 11, 2009

(30) Foreign Application Priority Data
May 11, 2009 (TW) 98115567

(51) Int. Cl. H01L 33/00

(52) U.S. Cl. 257/88; 257/98; 438/27; 257/E33.056; 257/E33.068

(57) ABSTRACT

The invention relates to a light emitting diode device having a light extracting rough structure. The device includes a leadframe, one or more light emitting diode chips provided on and electrically connected to the leadframe, and a lens configured to encapsulate the one or more light emitting diode chips, the lens having a surface including a micro-roughness structure. The micro-roughness structure of the lens has a roughness between 0.1 μm and 50 μm. The invention also relates to a method of manufacturing a light emitting diode device having a light extracting rough structure.

### CLAIM OF PRIORITY

This application claims the priority benefit of Taiwan Application Serial Number 98115567, filed on May 11, 2009. All disclosure of the Taiwan application is incorporated herein by reference.

### BACKGROUND OF THE INVENTION

1. Field of the Invention

The invention relates to an light emitting diode device having a light extracting rough structure and manufacturing methods thereof, wherein the light extracting rough structure has a micron-scaled roughness to improve light extraction efficiency and uniformity of the light emitting diode.

2. Description of Related Art

In a conventional LED device, there is a lens structure which is disposed on the LED. However, total reflection effect reduces light extraction efficiency in the LED structure. FIG. 1 is a schematic diagram showing a conventional LED device. As shown in FIG. 1, a LED 110 is encapsulated by a lens 120. When the light is emitted from the LED, there are two phenomena. If the angle of incidence is smaller than the critical angle, the light transmits through the surface 125 (shown by arrow A). If the angle of incidence is larger than the critical angle, the light reflects back to the lens. The total reflection reduces the light extraction efficiency of LED device.

### BRIEF SUMMARY OF THE INVENTION

This invention provides a LED device having a light extracting rough structure and manufacturing methods thereof.

This invention provides a LED device which has a light extracting rough structure. The device includes a leadframe, one or more light emitting diode chips disposed on and electrically connected to the leadframe, and a lens configured to encapsulate the one or more light emitting diode chips, the lens having a micro-roughness structure. This micro-roughness structure of the lens has a roughness between 0.1 μm and 50 μm. The device may include a protective layer made of a transparent glue and located between the lens and the one or more light emitting diode chips to protect the one or more light emitting diode chips.

The invention also provides a manufacturing method to produce a light emitting diode device having a light extracting rough structure. The manufacturing method includes the steps: disposing one or more light emitting diode chips on a leadframe and allowing the one or more light emitting diode chips to be electrically connected to the leadframe to form a semi-finished product; placing the semi-finished product inside a mold, the mold having been treated to have a micro-roughness structure in the inner surface; injecting a glue into the mold and curing the glue by heating, the glue forming a lens after curing, the lens encapsulating the one or more light emitting diode chips and having a surface including a micro-roughness structure; and retrieving the encapsulated light emitting diode chips and leadframe from the mold. The micro-roughness structure has a roughness between 0.1 μm and 50 μm. Furthermore, before placing the semi-finished product inside the mold, a protective layer can be dispensed on the one or more light emitting diode chips to protect the one or more light emitting diode chips. The protective layer can be a transparent glue or a glue mixed with fluorescent bodies.

The invention also provides a manufacturing method to produce a light emitting diode device having a light extracting rough structure. The manufacturing method includes the steps: disposing one or more light emitting diode chips on a leadframe and allowing the one or more light emitting diode chips to be electrically connected to the leadframe to form a semi-finished product; placing the semi-finished product inside a mold; injecting a glue into the mold and curing the glue by heating, the glue forming a lens after curing, the lens encapsulating the one or more light emitting diode chips; retrieving the encapsulated light emitting diode chips and leadframe from the mold; and roughening the surface of the lens to form a micro-roughness structure. The micro-roughness structure of the lens has a roughness between 0.1 μm and 50 μm. Furthermore, before placing the semi-finished product inside the mold, a protective layer can be dispensed on the one or more light emitting diode chips to protect the one or more light emitting diode chips. The protective layer can be a transparent glue or a glue mixed with fluorescent bodies.

### BRIEF DESCRIPTION OF THE DRAWINGS

The advantages and features of the invention will be appreciated by learning the various embodiments and examples set forth below in conjunction with the accompanied drawings. The drawings should be regarded as exemplary and schematic, and are shown not to scale and should not be implemented exactly as shown. In addition, like reference numerals designate like structural elements in the drawings.

FIG. 1 is a schematic diagram showing a conventional LED device;

FIG. 2 is a schematic diagram of a LED device having a light extracting rough structure according to an embodiment of the invention;

FIG. 3 is a schematic diagram of a LED device having a light extracting rough structure according to another embodiment of the invention;

FIG. 4A is a schematic enlarged diagram of part of the roughened surface in FIG. 2;

FIG. 4B is a schematic enlarged diagram of part of the roughened surface in FIG. 3;

FIG. 5 is a manufacturing flow chart of a LED device according to an embodiment of the invention;

FIGS. 6A to 6D are schematic diagrams showing specific steps in the manufacturing process depicted in FIG. 5;

FIG. 7 is a manufacturing flow chart of a LED device according to another embodiment of the invention;

FIGS. 8A and 8B are schematic diagrams showing the specific steps in part of the manufacturing process depicted in FIG. 7; and

FIG. 9 is a manufacturing flow chart of a LED device according to yet another embodiment of the invention.

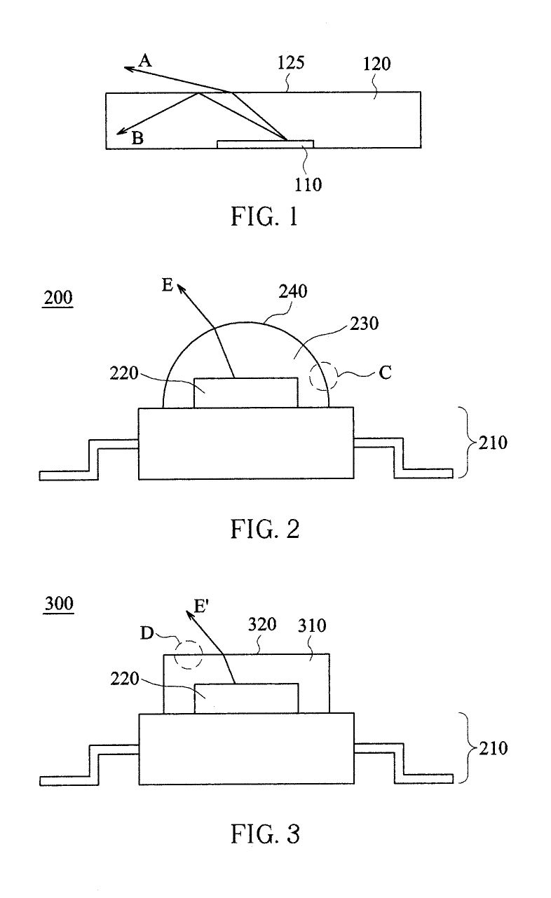

### DETAILED DESCRIPTION OF THE INVENTION

FIG. 2 is a schematic diagram showing a light emitting diode (LED) device 200 having a light extracting rough structure according to an embodiment of the invention. As shown in FIG. 2, the LED device 200 includes a leadframe 210, a LED chip 220 electrically connected to the leadframe 210, and a semi-spherical lens 230 configured to encapsulate the LED chip 220 and having a roughened surface 240. FIG. 3 is a schematic diagram showing a LED device 300 having a light extracting rough structure according to another embodiment of the invention. As shown in FIG. 3, the LED device 300 has a structure similar to that of the LED 200 in FIG. 2, except that while the lens 230 of the LED device 200 in FIG. 2 is semi-spherical, the lens 310 of the LED device 300 in FIG. 3 is rectangular. Similarly, the lens 310 in FIG. 3 also has a roughened surface 320. The roughened surfaces 240 and 320 have micro-roughness structures having a roughness between 0.1 μm and 50 μm. The roughened surfaces 240 and 320 can improve the light extraction efficiency and uniformity of the LED devices 200 and 300, respectively. Specifically, as shown in FIG. 2, when light is emitted from the LED chip 220, it is directed out of the LED device 200 by the roughened surface 240 of the semi-spherical lens 230 (as shown by arrow E in FIG. 2). Likewise, as shown in FIG. 3, when light is emitted from the LED chip 220, it is directed out of the LED device 300 by the roughened surface 320 of the rectangular lens 310 (as shown by arrow E′ in FIG. 3). In addition, in FIGS. 2 and 3, the LED chip 220 can be electrically connected to the leadframe 210 via wire (not shown) but the connection is not limited to wire. In other embodiments, the LED chip 220 can be electrically connected to the leadframe 210 using flip chip packaging. Further, although there is only one LED chip 220 shown in FIG. 2 or 3, it will be appreciated that each of the LED devices 200 and 300 of the invention can actually include one or more LED chips 220.

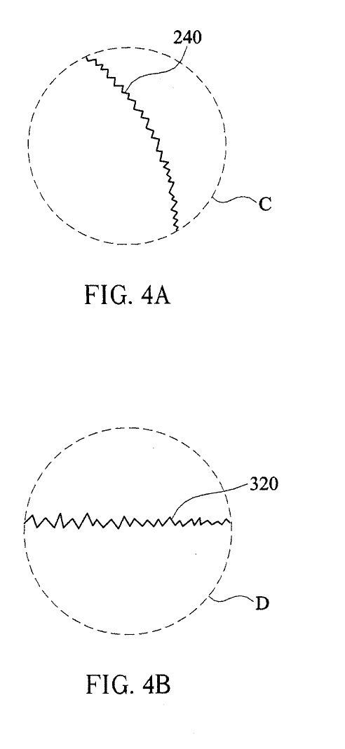

FIG. 4A is a schematic enlarged diagram showing part of the roughened surface 240 in FIG. 2 (i.e. the portion circled as C). FIG. 4B is a schematic enlarged diagram showing part of the roughened surface 320 in FIG. 3 (i.e. the portion circled as D). It can be clearly seen in FIGS. 4A and 4B that the roughened surfaces 240 and 320 have irregularly jagged shapes. When the LED chip 220 emits light, these irregularly jagged shapes on the roughened surfaces can help reduce the total reflection occurred in the lens.

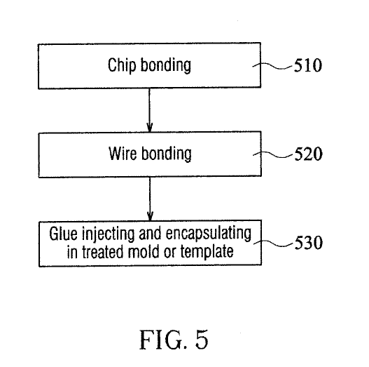

FIG. 5 is a manufacturing flow chart of a LED device according to an embodiment of the invention. As shown in FIG. 5, a LED chip is disposed on a leadframe in step 510 (the chip bonding step). In step 520, the LED chip is electrically connected to the leadframe via wire made of, for example, gold (Au) to form a semi-finished product of the LED device (the wire bonding step). In step 530, the semi-finished product is placed inside a treated (roughened) mold or template before a glue is injected into the mold or template and cured by heating, and then the finished product is retrieved from the mold or template (the glue injecting and encapsulating step).

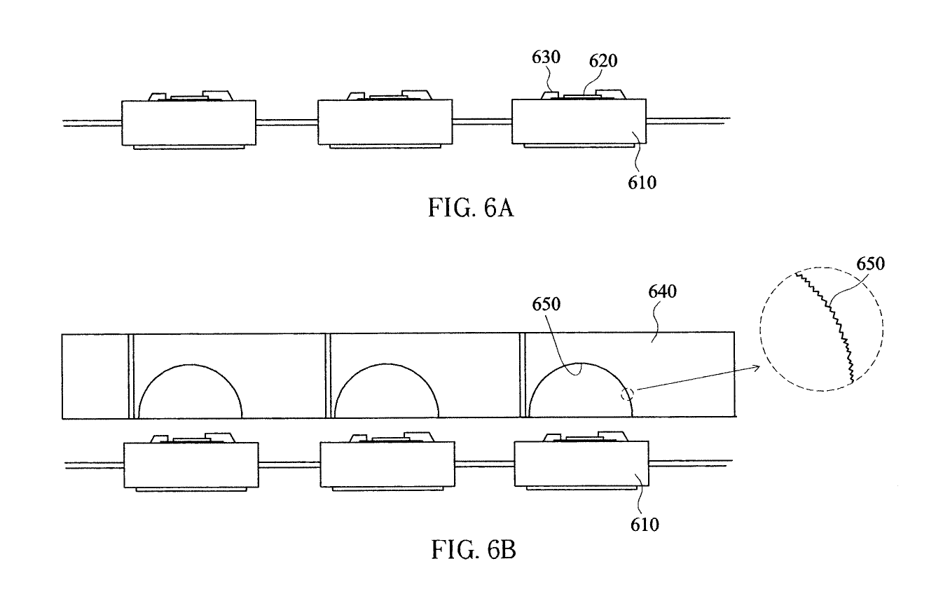

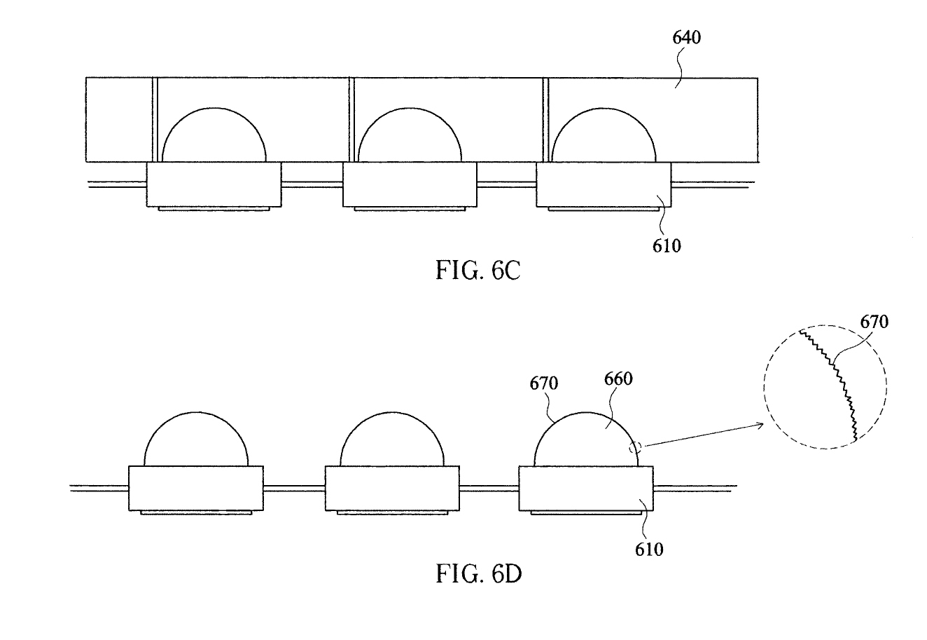

FIGS. 6A to 6D are schematic diagrams showing specific steps in the manufacturing process in FIG. 5. FIG. 6A illustrates the specific steps 510 and 520 depicted in FIG. 5. As shown in FIG. 6A, a LED chip 620 is disposed on a leadframe 610 and is electrically connected to the leadframe 610 via wire 630 so as to form a LED semi-finished product. FIGS. 6B to 6D illustrate the specific step 530 depicted in FIG. 5. As shown in FIGS. 6B to 6D, the semi-finished product (composed of leadframe 610, LED chip 620, and wire 630) of FIG. 6A is placed inside a treated (roughened) mold or template 640. The mold or template has an irregularly jagged inner surface 650 (as shown in the enlarged portion circled in FIG. 6B). After the mold or template 640 is roughened, the jagged inner surface 650 can have a micro-roughness structure having a roughness between 0.1 μm and 50 μm. Next, as shown in FIG. 6C, a glue such as epoxy or silicone is injected into the mold or template 640, and the glue is heated to cure. Finally, as shown in FIG. 6D, the final product is allowed to separate from the mold or template 640. The final product is composed of leadframe 610, LED chip 620, wire 630, and lens 660, wherein the lens 660 is cured by heating the glue. The lens has an irregularly jagged surface 670 (as shown in the enlarged portion circled in FIG. 6D) resulted from the jagged inner surface 650 of the mold or template 640. The jagged surface 670 also has a micro-roughness structure between 0.1 μm and 50 μm. The jagged inner surface 650 of the mold or template 640 is formed by using one of sand blasting, chemical etching, and electrochemical etching so that the jagged inner surface 650 has the micro-roughness structure having a roughness between 0.1 μm and 50 μm.

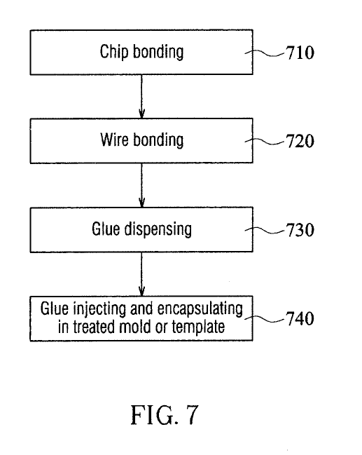

FIG. 7 is a manufacturing flow chart of a LED device according to another embodiment of the invention. As shown in FIG. 7, a LED chip is disposed on a leadframe in step 710 (the chip bonding step). In step 720, the LED chip is electrically connected to the leadframe via wire made of, for example, gold (Au) (the wire bonding step). In step 730, a glue dispensing process is performed, wherein a transparent glue optionally containing fluorescent bodies is coated over the LED chip and the wire so as to completely encapsulate the LED chip and partially encapsulate the wire (the glue dispensing step) to form a semi-finished product of the LED device. The transparent glue used in step 730 can be configured as a protective layer for the LED chip and wire. The transparent glue can also be configured to secure the carrier layer of the fluorescent bodies when the LED device needs different types of fluorescent bodies to emit light with different wavelengths. The transparent glue can be silicone. In step 740, the semi-finished product is placed inside a treated (roughened) mold or template before the glue is injected into the mold or template and heated, and then when the glue is cured after heating, the final product is retrieved from the mold or template (the glue injecting and encapsulating step). The manufacturing flow chart depicted in FIG. 7 is similar to that in FIG. 5, except that in FIG. 7 the LED chip and wire are coated with the transparent glue optionally containing fluorescent bodies (i.e. the glue dispensing step).

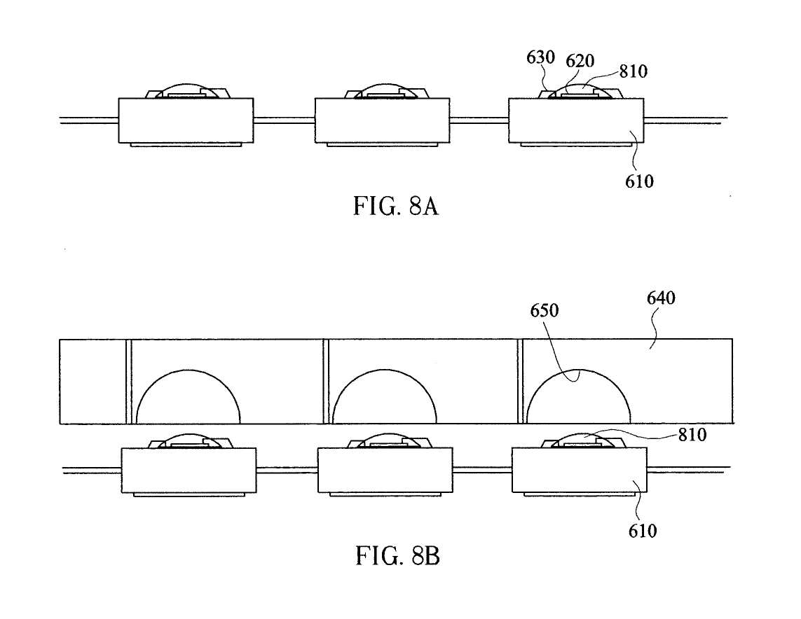

FIG. 8A is a schematic diagram showing the specific steps 710 to 730 depicted in FIG. 7. FIG. 8B shows that the semi-finished product depicted in FIG. 6B is placed inside the same mold or template 640. As compared to FIG. 6A, the semi-finished product of the LED device of FIG. 8A can be composed of leadframe 610, LED chip 620, wire 630, and protective layer 810 (and/or carrier layer) optionally containing fluorescent bodies. In FIG. 7, all the steps but step 730 are similar to those in FIG. 5. This means that step 710 corresponds to step 510; step 720 corresponds to step 520; and step 740 corresponds to step 530 (as shown in FIGS. 6C and 6D); hence, these steps will not be described here for brevity. Although FIGS. 6A and 8A show that each LED device has only one LED chip 620, it is understood that the LED device of the invention can actually include one or more LED chips 620.

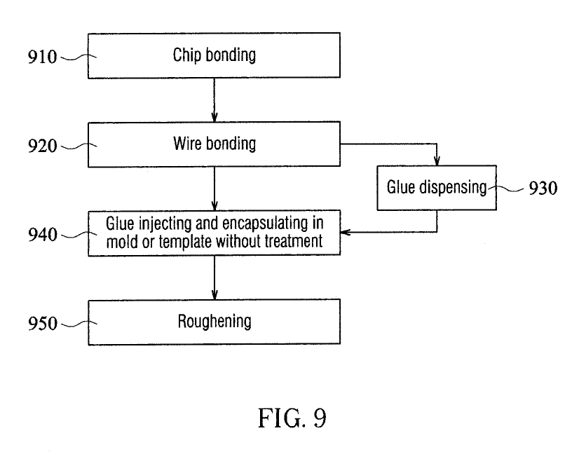

In other embodiments of the invention, the treated (roughened) mold or template may not be required. FIG. 9 is a manufacturing flow chart of a LED device according to yet another embodiment of the invention. As shown in FIG. 9, a LED chip is disposed on a leadframe in step 910 (the chip bonding step). In step 920, the LED chip is electrically connected to the leadframe via wire made of, for example, gold (Au) to form a semi-finished product of the LED device (the wire bonding step). In step 930, a glue dispensing process is performed, wherein a transparent glue optionally containing fluorescent bodies is coated over the LED chip and wire so as to completely encapsulate the LED chip and partially encapsulate the wire (the glue dispensing step). However, step 930 is not necessary and can be omitted in other embodiments. In step 940, the semi-finished product of the LED device is placed inside a mold or template having no treated inner surface before a lens having no jagged surface is formed by using the above mentioned curing-by-heating step, and then the final product is retrieved from the mold or template (the glue injecting and encapsulating step). Finally, in step 950, the surface of the lens is roughened by a method such as etching or imprinting, thereby forming a lens surface with an irregularly jagged shape (the surface roughening step). After being roughened, the surface of the lens has a micro-roughness structure having a roughness between 0.1 μm and 50 μm. The etching method can be performed to achieve the desired roughness, for example, by etching the surface of the lens with methylbenzene at about room temperature to about 60° C. for about 30 seconds to about 1 hour. On the other hand, the imprinting method can be performed to achieve the desired roughness, for example, by selectively printing silicone on the surface of the lens and curing it at about 150° C. for about 30 minutes.

According to the methods of the invention, LED devices having the light extracting rough structures of the same roughness can be simultaneously manufactured in mass production.

Although the foregoing invention has been described in the preferred embodiments in conjunction with the drawings for purposes of clarity of understanding, it will be apparent to the person skilled in the art that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A light emitting diode device having a light extracting rough structure, the device comprising:
a leadframe;
one or more light emitting diode chips disposed on and electrically connected to the leadframe; and
a lens configured to encapsulate the one or more light emitting diode chips, the lens having a surface including a micro-roughness structure.

2. The light emitting diode device of claim 1, wherein the surface of the micro-roughness structure of the lens has a roughness between 0.1 μm and 50 μm.

3. The light emitting diode device of claim 1, further comprising:
a protective layer made of a transparent glue and located between the lens and the one or more light emitting diode chips to protect the one or more light emitting diode chips.

4. The light emitting diode device of claim 3, wherein the protective layer includes fluorescent bodies.

5. The light emitting diode device of claim 3, wherein the transparent glue is silicone.

6. The light emitting diode device of claim 1, wherein the lens is made of a glue.

7. The light emitting diode device of claim 6, wherein the glue is epoxy or silicone.

8. A method of manufacturing a light emitting diode device having a light extracting rough structure, the method comprising the following steps of:
disposing one or more light emitting diode chips on a leadframe and allowing the one or more light emitting diode chips to be electrically connected to the leadframe to form a semi-finished product;
placing the semi-finished product inside a mold, the mold having been treated to have a micro-roughness structure in the inner surface;
injecting a glue into the mold and curing the glue by heating, the glue forming a lens after curing, the lens encapsulating the one or more light emitting diode chips and having a micro-roughness structure in the surface; and
retrieving the encapsulated light emitting diode chips and leadframe from the mold.

9. The method of claim 8, wherein the micro-roughness structure in the inner surface of the mold has a roughness between 0.1 μm and 50 μm.

10. The method of claim 9, wherein the treatment of the mold includes sand blasting, chemical etching, or electrochemical etching.

11. The method of claim 8, wherein the surface of micro-roughness structure of the lens has a roughness between 0.1 μm and 50 μm.

12. The method of claim 8, further comprising:
dispensing a protective layer on the one or more light emitting diode chips to protect the one or more light emitting diode chips before placing the semi-finished product inside the mold, the protective layer being made of a transparent glue.

13. The method of claim 12, wherein the protective layer includes fluorescent bodies.

14. The method of claim 12, wherein the transparent glue is silicone.

15. The method of claim 8, wherein the glue is epoxy or silicone.

16. A method of manufacturing a light emitting diode device having a light extracting rough structure, the method comprising the following steps of:
disposing one or more light emitting diode chips on a leadframe and allowing the one or more light emitting diode chips to be electrically connected to the leadframe to form a semi-finished product;
placing the semi-finished product inside a mold;
injecting a glue into the mold and curing the glue by heating, the glue forming a lens after curing, the lens encapsulating the one or more light emitting diode chips;
retrieving the encapsulated light emitting diode chips and leadframe from the mold; and
roughening the surface of the lens to form a micro-roughness structure.

17. The method of claim 16, wherein the surface of the micro-roughness structure of the lens has a roughness between 0.1 μm and 50 μm.

18. The method of claim 16, wherein the roughening includes etching or imprinting.

19. The method of claim 16, further comprising:
dispensing a protective layer on the one or more light emitting diode chips to protect the one or more light emitting diode chips before placing the semi-finished product inside the mold, the protective layer being made of a transparent glue.

20. The method of claim 19, wherein the protective layer includes fluorescent bodies.

21. The method of claim 19, wherein the transparent glue is silicone.

22. The method of claim 16, wherein the glue is epoxy or silicone.

23. The method of claim 18, wherein the etching includes etching the surface of the lens with methylbenzene at room temperature to 60° C. for 30 seconds to 1 hour.

24. The method of claim 18, wherein the imprinting includes selectively printing silicone on the surface of the lens and curing the silicone at 150° C. for 30 minutes.
